(19) United States
(12) Patent Application Publication
(10) Pub. No.: US 2005/0231233 A1
(43) Pub. Date: Oct. 20, 2005

(54) Semiconductor integrated circuit device

(76) Inventors: Jun Kasai, Higashimurayama (JP); Koji Takada, Hitachinaka (JP); Masato Suzuki, Fuchu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/106,470

(22) Filed: Apr. 15, 2005

(30) Foreign Application Priority Data
Apr. 15, 2004 (JP) 2004-119795

(51) Int. Cl. H03K 19/0175

(52) U.S. Cl. 326/33

(57) ABSTRACT

To improve reliability of a bus interface by restraining fluctuation in characteristics of an input circuit, such as threshold voltage, temperature and power source voltage, when an input signal shifts from Hi level to Lo level, transistor MP3 is OFF until the input signal lowers to a logic threshold value; and, by comparing a reference voltage and an input signal the low level input voltage shifts to the level of the difference voltage. When the input signal shifts from Lo level to Hi level, transistor MP3 is ON until the input signal exceeds the logic threshold value, the High level input voltage is increased by the amount of current of transistor MP4. The current of transistor MP4 is proportional to the current of transistor MN1, and, therefore, the High level input voltage becomes constant, and is not influenced by the threshold voltage, the temperature of the transistor, and power source voltage.

### CROSS-REFERENCE TO RELATED APPLICATION

The present application claims priority from Japanese patent application No.2004-119795, filed on Apr. 15, 2004, the content of which is hereby incorporated by reference into this application.

### BACKGROUND OF THE INVENTION

The present invention relates in general to a technology to be used for stably operating an input circuit; and, more particularly, the invention relates to a technology that is effective in restraining fluctuation in characteristics of an input circuit of a bus interface.

### DESCRIPTION OF THE RELATED ART

In recent years, a camera has been included in the electronic system of a portable telephone or PDA (Personal Digital Assistant), and there is a widely known technology for controlling a camera module comprising the camera system via an I²C bus interface, which is used as a control bus.

The I²C bus interface is provided in conformity with an I²C bus (Inter IC Bus) proposed by Philips corporation, and the I²C bus interface is constituted as a bi-directional two line bus comprising a serial data line and a serial clock line in respective channels.

In an I/O (Input/Output) circuit provided at the I²C bus interface, a Schmidt trigger circuit is used in an input circuit. The input circuit is constituted by, for example, a transistor for generating an input hysteresis and two inverters having a CMOS (Complementary Metal Oxide Semiconductor) constitution. The transistor for generating the hysteresis is connected in series either between a portion connecting the two inverters and a power source voltage VCC or between a portion connecting the two inverters and a reference potential VSS.

Further, there is an input circuit for generating a hysteresis of this kind, which includes a differential amplifying circuit and a Schmidt circuit having a predetermined input hysteresis width for inputting and adjusting the shape of an output signal of the differential amplifying circuit for preventing an erroneous operation in response to an inputted small amplitude signal due to high frequency noise (refer to Patent Reference 1).

(Patent Reference 1) JP-A-09-172363

However, it has been found by the inventors that the following problem exists in the above-described technology used for generating a hysteresis in the input circuit. That is, the input circuit provided with a transistor for generating the hysteresis has the problem that the Low level input voltage ViL and the High level input voltage ViH and the hysteresis are dependent on the threshold voltage and the temperature of the transistor, and it is very difficult to restrain a fluctuation in these characteristics. Thereby, there is a danger of deteriorated reliability in the I²C bus interface.

### SUMMARY OF THE INVENTION

It is an object of the present invention to provide a semiconductor integrated circuit device in which a considerably improved reliability of a bus interface can be attained by restraining fluctuation in the characteristics of an input circuit, which characteristics are dependent on the threshold voltage, temperature and power source voltage.

The above-described object, other objects and novel characteristics of the invention will be made clear by the following description and the attached drawings.

A simple explanation will be given of a representative aspect of the invention disclosed in this application.

A semiconductor integrated circuit device in accordance with the invention is provided with an input circuit including a hysteresis generating portion for generating a desired hysteresis and a differential input circuit for comparing the input signal and a reference voltage after the input signal shifts from Hi level to Lo level due to the hysteresis of the hysteresis generating portion, and wherein an inverse signal is outputted when the input signal is at a voltage level which is substantially the same as the reference voltage.

Further, another aspect of the invention will be simply described as follows.

A semiconductor integrated circuit device in accordance with the invention is provided with an input circuit including a differential input circuit for comparing an input signal and a reference voltage after the input signal shifts from Hi level to Lo level, and wherein an inverse signal is outputted when the input signal is at a voltage level which is substantially the same as the reference voltage and outputting the inverse signal is outputted when the input signal is at a voltage level higher than the reference voltage after the input signal shifts from the Lo level to the Hi level, and a hysteresis generating portion is provided for generating a desired hysteresis.

A simple explanation will be given of the effects achieved by the present invention as follows.
(1) A fluctuation in characteristic s according to the threshold voltage, temperature and power source voltage can be restrained, and, therefore, even when the power source voltage is low, communication can be stably carried out.
(2) Owing to the above-described effect (1), the reliability of the semiconductor integrated circuit device can be considerably promoted.

### BRIEF DESCRIPTION OF THE DRAWINGS

FIG. 1 is a schematic diagram showing the constitution of an input/output circuit according to an embodiment of the invention;

FIG. 2 is a circuit diagram showing an example of an input circuit provided in the input/output circuit of FIG. 1;

FIG. 3 is a graph showing a relationship between input voltage and output voltage in the input circuit of FIG. 2;

FIG. 4 is a chart showing specifications of the input circuit of FIG. 2;

FIG. 5 is a circuit diagram showing an example of a reference voltage source provided in the input/output circuit of FIG. 1;

FIG. 6 is a schematic diagram showing another example of a reference voltage source provided in the input/output circuit of FIG. 1;

FIG. 7 is a schematic diagram showing still another example of a reference voltage source provided in the input/output circuit of FIG. 1;

FIG. 8 is a circuit diagram showing another example of the input circuit provided in the input/output circuit of FIG. 1;

FIG. 9 is a circuit diagram showing an example of the input circuit provided at the input/output circuit of FIG. 1, which improves the common mode voltage;

FIG. 10 is a circuit diagram showing another example of the input circuit provided at the input/output circuit of FIG. 1;

FIG. 11 is a block diagram showing a partial constitution of a portable telephone using the input/output circuit of FIG. 1; and

FIG. 12 is a circuit diagram of an input circuit according to another embodiment of the invention.

### DETAILED DESCRIPTION OF THE PREFERRED EMBODIMEMTS

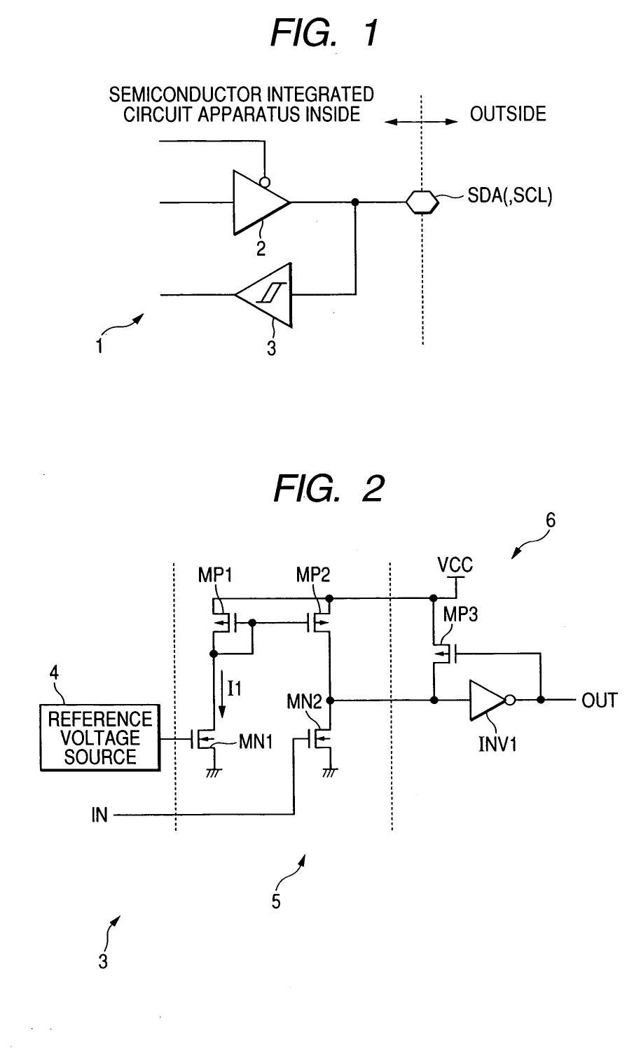

An embodiment of the present invention and modifications thereof will be explained in detail with reference to FIGS. 1 through 11 of the drawings.

According to this embodiment, the input/output circuit 1 is used as an I/O in a bus interface provided at a semiconductor integrated circuit device.

The bus interface comprises an I²C bus interface, which is an interface for a bi-directional two line bus (serial data and serial clock) for controlling communications between ICs.

As shown in FIG. 1, the input/output circuit 1 is constituted by an output circuit 2 and an input circuit 3, which are respectively connected to a serial data terminal SDA and a serial clock terminal SCL in an I²C bus.

The output circuit 2 transmits data (or a clock signal), which has been outputted from a logic circuit inside the semiconductor integrated circuit device, to the outside via the serial data terminal SDA (or serial clock terminal SCL).

The input circuit 3, which is a serial data input portion, (or serial clock input portion) transmits data (or clock signal) inputted via the serial data terminal SDA (or serial clock terminal SCL) to the logic circuit inside the semiconductor integrated circuit device.

FIG. 2 is a circuit diagram showing an example of the input circuit 3. As illustrated, the input circuit 3 is constituted by a reference voltage source 4, a differential input portion (differential input circuit) 5 and a hysteresis generating portion 6. The reference voltage source 4 generates the desired reference voltage VREF.

The differential input portion 5 is constituted by transistors MP1, MP2, each comprising a P-channel MOS FET (Field Effect Transistor), and transistors MN1, MN2, each comprising an N-channel MOS FET. The hysteresis generating portion 6 is constituted by a transistor MP3, comprising a P-channel MOS FET and an inverter INV1.

One of the connection portions of each of the transistors MP1 through MP3 are connected with a power source voltage VCC, and the other connecting portion of the transistor MP1 is connected with the gates of the transistors MP1, MP2 and with a connecting portion on one side of the transistor (first transistor) MN1.

The gate of the transistor MN1 is connected to receive the reference voltage VREF generated by the reference voltage source 4, and the other connecting portion of the transistor MN1 is connected with a reference potential VSS.

A connecting portion on the other side of the transistor MP2 is connected with a connecting portion on one side of the transistor (second transistor) MN2, a connecting portion on the other side of the transistor MP3 and the input portion of the inverter INV1.

The gate of the transistor MN2 is connected to receive an input signal IN inputted via the serial data terminal SDA (or serial clock terminal SCL), and a connecting portion on the other side of the transistor MN2 is connected with the reference potential VSS.

The gate of the transistor MP3 is connected with an output portion of the inverter INV1, and the output portion of the inverter INV1 constitutes an output portion providing an output signal OUT of the input circuit 3.

Next, an explanation will be given of the operation of the input circuit 3 according to this embodiment.

First, in the differential input portion 5 of the input circuit 3, the voltage levels of the reference voltage VREF generated by the reference voltage source 4 and the input signal IN are compared, and the reference voltage VREF constitutes a logic threshold.

For example, when the input signal IN shifts from a Hi level to Lo level, the transistor MP3 is OFF until the input signal IN becomes equal to or smaller than the logic threshold; thus, when the voltage level of the input signal IN becomes the same as the reference voltage VREF, the output signal OUT becomes Lo level.

That is, the reference voltage VREF is equal to a low level input voltage ViL, and the low level input voltage ViL can be controlled by appropriately generating the reference voltage VREF.

Further, when the input signal IN shifts from Lo level to Hi level, the transistor MP3 is ON until the input signal IN exceeds the logic threshold, the logic threshold becomes higher than that when the transistor MP3 is OFF, and the voltage becomes the High level input voltage ViH.

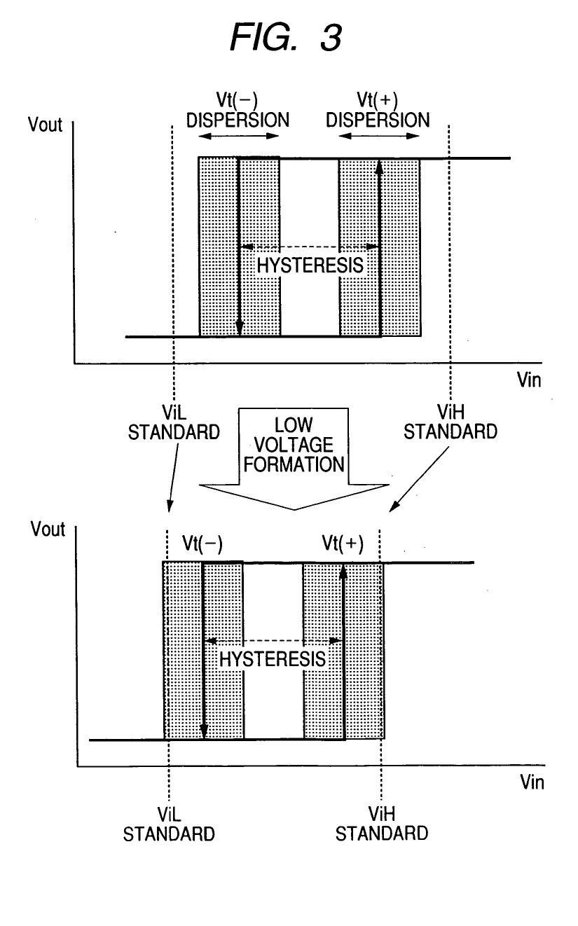

FIG. 3 provides graphs showing the relationship between the input voltage Vin of the input signal IN and the output voltage Vout of the output signal OUT for different values of the power source voltage VCC.

The upper half of FIG. 3 shows a case in which the power source voltage VCC is equal to or higher than 2.0 V, and the lower half of FIG. 3 shows a case in which the power source voltage VCC is lower than 2.0 V. In both diagrams, the dotted line on the left side designates the standard Low level voltage ViL, and the dotted line on the right side designates the High level input voltage ViH.

Further, the shaded region on the left side designates fluctuation of the logical threshold Vt (−) on the Lo level side of the input circuit and the shaded region on the right side designates fluctuation of the logical threshold Vt (+) on the Hi level side of the input circuit 3.

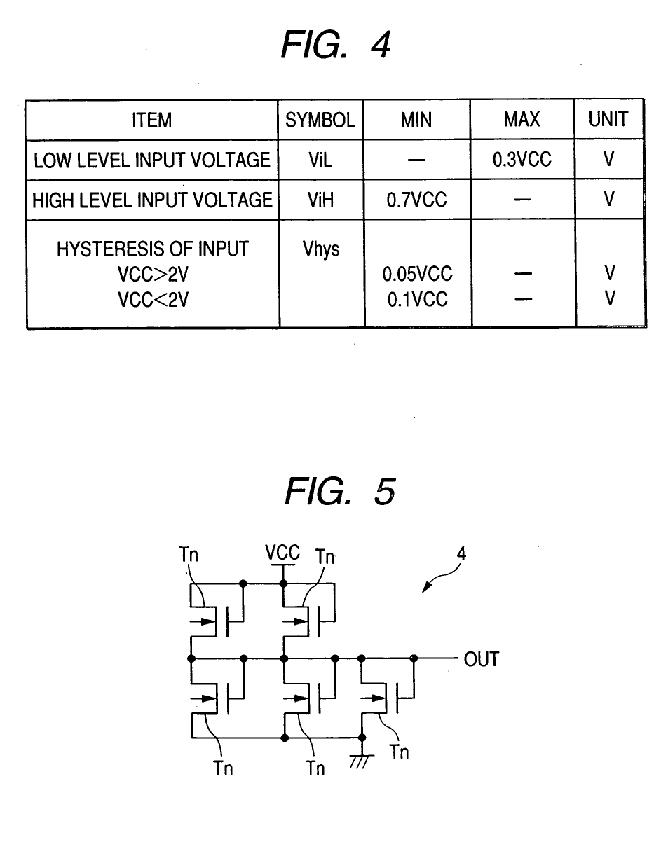

An explanation will be given here of the specifications of the input circuit 3 in the I²C bus prescribed in Document order Number. 9398 393 40011 “THE I2C-PUS SPECIFICATION VERSION 2.1” issued by Koninklijke Philips Electronics N.V., with reference to FIG. 4.

Standard values of the Low level input voltage ViL, the High level input voltage ViH and the hysteresis are determined based on the power source voltage VCC. Further, the standard value of the hysteresis differs according to whether the power voltage VCC is no less than 2V or is lower than 2V.

For example, when the power source voltages VCC that are 2.0 V or higher and those that are lower than 2.0 V are compared, as can be seen, although the standard values of the Low level input voltage ViL and the High level input voltage ViH are reduced in direct proportion with the power source voltage VCC, the minimum value of the hysteresis Vhys is conversely increased.

Therefore, as shown in FIG. 3, when the power source voltage VCC becomes lower than 2.0 V, although the standard values of the Low level input voltage ViL and the high level input voltage ViH are reduced in direct proportion with changes in the power source voltage VCC, the minimum value of the hysteresis Vhys is increased, and, therefore, there is a concern that the specifications cannot be satisfied owing to the fluctuations in the logical thresholds Vt (−), Vt (+).

On the other hand, in the case of the input circuit 3 having the hysteresis generating portion 6 according to the present invention, fluctuation in the characteristic of the Low level input voltage ViL can be restrained without controlling any fluctuation which may occur in fabricating the transistor, in the temperature and the like.

FIG. 5 through FIG. 7 are circuit diagrams showing examples of the reference voltage source 4.

The circuit of FIG. 5 is constituted by a plurality of transistors Tn, each in the form of an N-channel MOS FET. In this case, a first and a second group of transistors Tn are respectively connected in parallel between the power source voltage VCC and the reference potential VSS, and the reference voltage VREF is generated by the divided voltage which is dependent on the ON resistance ratio of the transistors Tn constituting the first and the second groups transistors.

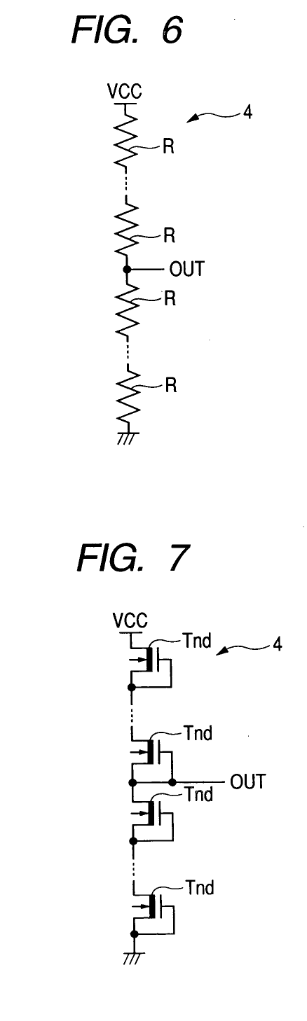

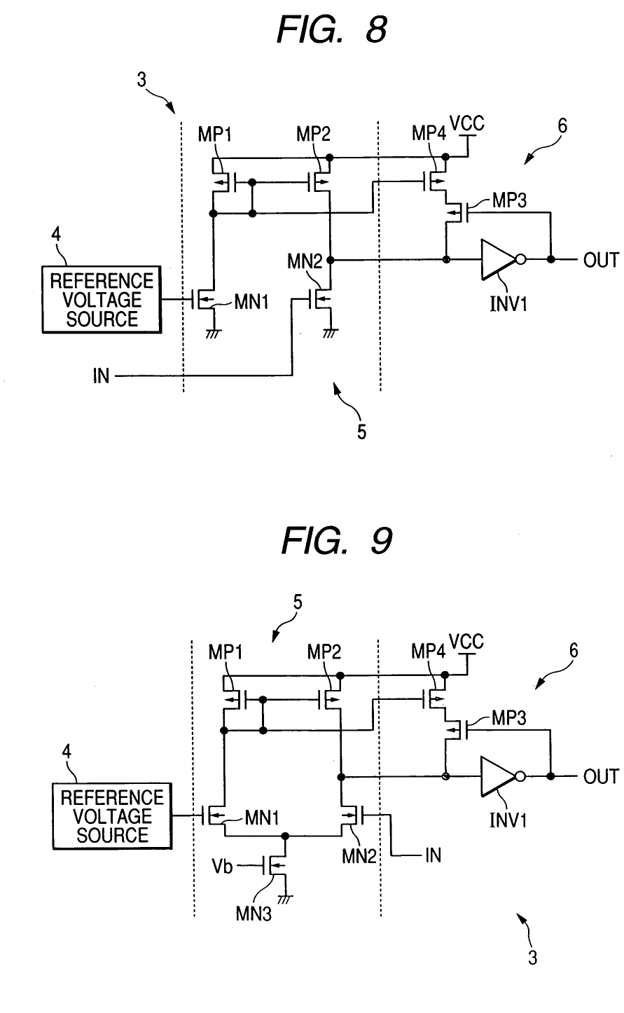

Further, FIG. 6 shows a circuit for generating the reference voltage VREF through the voltage division of a plurality of resistors R connected in series between the power source voltage VCC and the reference potential VSS. FIG. 7 shows a circuit connecting a plurality of transistors Tnd of the N-channel depletion type in series between the power source voltage VCC and the reference potential VSS for generating the reference voltage VREF through resistor voltage division of the respective transistors Tnd.

In this way, by the constitutions of FIG. 5 through FIG. 7, the reference voltage VREF can be generated in proportion to the power source voltage VCC. This is possible because the Low level input voltage ViL is dependent on the power source voltage VCC as shown by FIG. 4.

Further, the reference voltage source 4 may be provided as a constitution other than those of FIG. 5 through FIG. 7, for example, the reference voltage source 4 may be constituted by a band gap circuit.

Here, in the input circuit 3 shown in FIG. 2, although fluctuation in the characteristics of the Low level input voltage ViL can be restrained, as described above, the High level input voltage ViH and the hysteresis are dependent on the threshold voltage Vth of the transistor MP3, the power source voltage VCC and the temperature.

FIG. 8 is a circuit diagram showing another constitution of the input circuit 3 which is capable of restraining a fluctuation in the characteristics of not only the Low level input voltage ViL, but also of the High level input voltage ViH and the hysteresis.

The input circuit 3 of FIG. 8 differs from that of FIG. 2 in that a transistor (third transistor) MP4, which is a P-channel MOS FET, is newly provided at the hysteresis generating portion 6, while and constitutions of the reference voltage source 4 and the differential input portion 5 are similar to those of FIG. 2.

A connecting portion on one side of the transistor MP4 is connected with the power source voltage VCC, and the gate of the transistor MP4 is connected with the gates of the transistors MP1 and MP2, and, thereby, a current mirror circuit is constituted. By use of the current mirror circuit, a current which is proportional to that of the transistor MN1 can be made to flow in the transistor MP4.

The connecting portion on the other side of the transistor MP4 is connected with the connecting portion on one side of the transistor MP3, and a connecting portion on the other side of the transistor MP3 is connected to the input portion of the inverter INV1, similar to FIG. 2.

Next, the operation of the input circuit 3 shown in FIG. 8 will be explained.

First, when the input signal IN shifts from Hi level to Lo level, the transistor MP3 is OFF until the input signal IN decreases to the logic threshold value; and, by comparing the reference voltage VREF and the voltage of the input signal IN, the Low level input voltage ViL becomes the level of the reference voltage VREF.

Further, When the input signal IN shifts from Lo level to Hi level, the transistor MP3 is ON until the input signal IN exceeds the logic threshold value. The High level input voltage ViH is determined by the ratio of the current driving capability of the transistor MN2 to the transistor MP2+ the transistor MP4, in this case, the High level input voltage ViH is increased by the amount of the current of the transistor MP4.

However, since the current of the transistor MP4 is directly proportional to the current of the transistor MN1, the High level input voltage ViH becomes constant and does not depend on the threshold voltage Vth of the transistor, the temperature and the power source voltage VCC.

Thereby, the Low level input voltage ViL, the High level input voltage ViH and the hysteresis depend only on the reference voltage VREF, and, even in the case of the power source voltage VCC having a low voltage level (for example, equal to or lower than 2.0 V), fluctuation in the characteristics can be reduced considerably.

FIG. 9 is a circuit diagram showing an example of the input circuit 3 for improving the common mode voltage at the differential input portion 5. According to the input circuit 3 of FIG. 9, an N channel MOS FET (constant current source transistor) MN3 is newly provided at the differential input portion 5, while the constitutions of the reference voltage source 4 and the hysteresis generating portion 6 are similar to those of FIG. 8.

The connecting portion on one side of the transistor MN3 is connected with the connecting portions on the opposite sides of the transistors MN1, MN2, and a connecting portion on the other side of the transistor MN3 is connected with the reference potential VSS.

The gate of the transistor MN3 is connected to receive a bias potential Vb (or power source voltage VCC), and the transistor MN3 is operated as a constant current source of the differential input portion 5.

By providing the transistor MN3, the common mode potential of the differential input portion 5 can be made to be constant, and the width of the fluctuations of the Low level input voltage ViL, the High level input voltage ViH and the hysteresis can be further reduced.

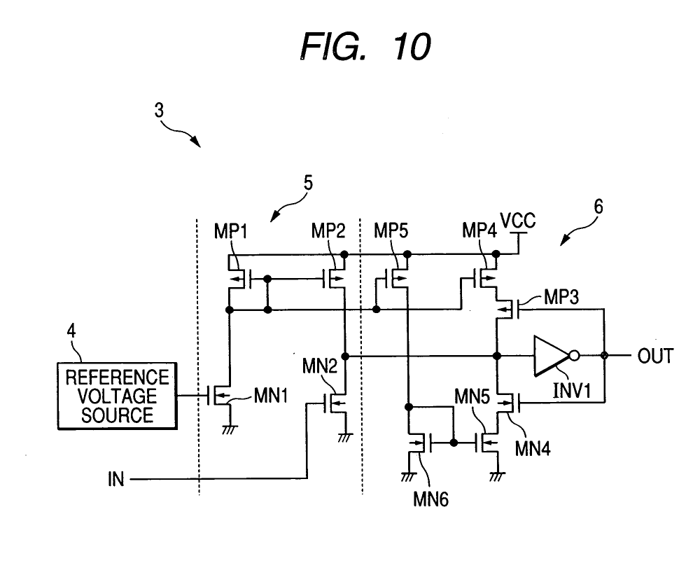

FIG. 10 shows an example of the input circuit 3 for generating the hysteresis not only by use of a P-channel MOS FET, but also use of by a transistor formed of a N-channel MOS FET.

According to the input circuit 3 of FIG. 10, a transistor MP5 found of a P-channel MOS FET and transistors MN4 through MN6 each formed of a N-channel MOS FET are newly provided to the hysteresis generating portion 6, while the and constitutions of the reference voltage source 4 and the differential input portion 5 are similar to those of FIG. 8.

The connecting portion on one side of the transistor MP5 is connected with the power source voltage VCC, and the gate of the transistor MP5 is connected with the gates of the transistors MP1, MP2.

The connecting portion on the other side of the transistor MP5 is respectively connected with the connecting portion on one side of the transistor MN6, the gate of the transistor MN6 and the gate of the transistor MN5. The connecting portion on one side of the transistor MN4 is connected with the input of the inverter INV1, and the gate of the transistor MN4 is connected with the output portion of the inverter INV1.

A connecting portion on the other side of the transistor MN4 is connected with the connecting portion on one side of the transistor MN5. Connecting portions on the other sides of the transistors MN5 and MN6 are respectively connected with the reference potential VSS.

In this case, a converting circuit is constituted by the transistors MP5, MN6, a current mirror is constituted by the transistor MP1 and the transistor MN5, and a current in proportion to that of the transistor MP1 is made to flow in the transistor MN4.

Thereby, at the hysteresis generating portion 6, the hysteresis is generated on the plus side by the transistor MP4 and the hysteresis is generated on the minus side by the transistor MN5.

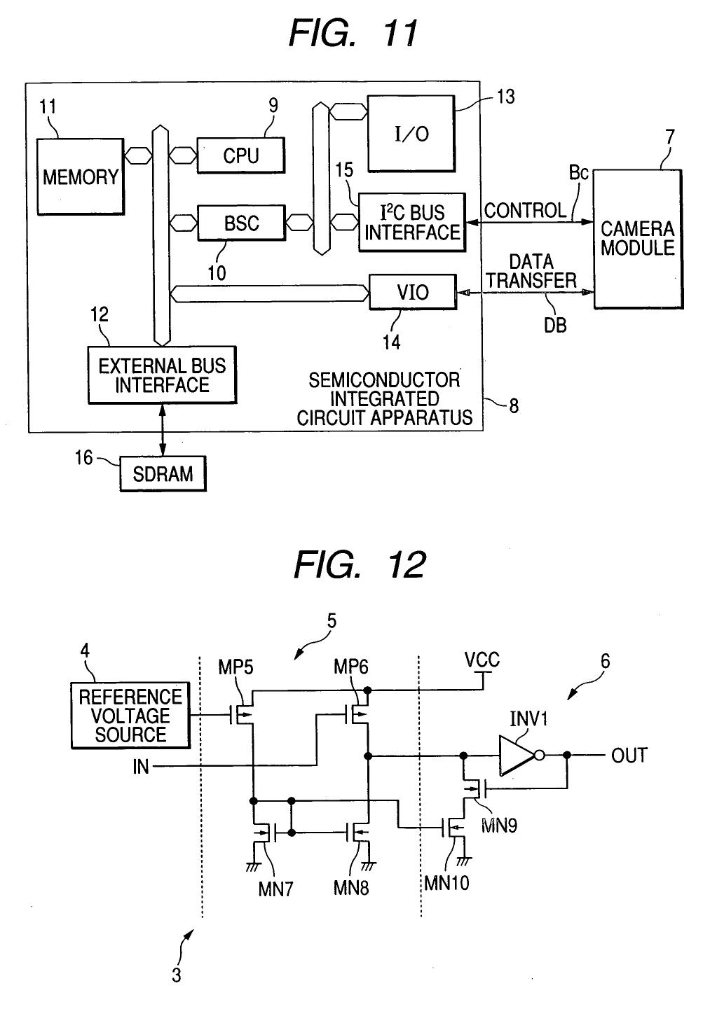

FIG. 11 is a block diagram showing a camera module 7, in a portable telephone of the type including a camera, and a semiconductor integrated circuit device 8.

The camera module 7, for example, includes a CMOS sensor and a processor for processing a camera signal, both installed in a single package, for taking a dynamic image, a stationary image, transmitting the image by e-mail and processing image data directly on a personal computer.

The semiconductor integrated circuit device 8 is a processor for performing all control functions in the portable telephone including the camera module 7. The camera module 7 and the semiconductor integrated circuit device 8 are connected via an I²C bus Bc, which is one of the control buses. The semiconductor integrated circuit device 8 controls various operations, such as adjusting the exposure and setting functions, by sending signals via the I²C bus Bc to the camera module 7.

The semiconductor integrated circuit device is constituted by CPU (Central Processing Unit) 9, a bus state controller (BSC) 10, a memory 11, an external bus interface 12, I/O 13, a video I/O module (VIO) 14 and an I²C bus interface 15. Further, the CPU 9, the bus state controller 10, the memory 11, the external bus interface 12, the I/O 13, the video I/O module 14, and the I²C bus interface 15 are connected to each other via a peripheral bus B.

The CPU 9 governs control of all of the semiconductor integrated circuit devices 8. The bus state controller 10 controls transmission of signals on the peripheral bus B and controls the state of the peripheral bus B.

The memory 11 comprises, for example, various memories, such as caches. The external bus interface 12 is an interface for devices, such as an SDRAM 16, which are connected to the semiconductor integrated circuit device 8. The SDRAM 16, for example, stores data consisting of default settings for the camera module 7.

Data representing, for example, a key input is inputted to and outputted from the I/O 13. Image data acquired by the camera module 7 is transmitted to the video I/O module 14 via a data bus DB. The I²C bus interface 15 is an interface at an I²C bus Bc. The I²C bus interface 15 is provided with the input/output circuit 1 (FIG. 1) and one of the input circuits 3 shown in FIG. 2 and FIG. 8 through FIG. 10 is used for the input/output circuit 1. In this way, by using the input circuit 3 at the input/output circuit 1 in the I²C bus interface 15 of the I²C bus Bc, communication between the camera module 7 and the semiconductor integrated circuit device can be stably executed, and, therefore, the reliability of an electronic system of the portable telephone or the like can be promoted.

Thereby, according to this embodiment, even when the power source voltage VCC is a low voltage, communication by the I²C bus Bc can be stably executed.

Although a specific explanation has been given of the present invention based on the embodiments described above, the invention is not limited to the above-described embodiments, but can naturally be modified variously within a range not deviated from the gist thereof.

For example, at the above-described embodiments, the N-channel MOS FET and the P-channel MOS FET of the input circuit shown in FIG. 8 may be interchanged. In this case, as shown by FIG. 12, the input circuit 3 is constituted by the reference voltage source 4, the differential input portion 5 and the hysteresis generating portion 6.

The differential input portion 5 comprises P-channel MOS FET MP5, MP6 and N-channel MOS FET MN7, MN8, and the hysteresis generating portion 6 is constituted by N-channel MOS FET MN9, MN10 and the inverter INV1.

Connecting portions on one side of the transistors MP5, MP6 are respectively connected with the power source voltage VCC, and the gate of the transistor MP5 is connected to receive the reference voltage VREF generated by the reference voltage source VREF. The gate of the transistor MP6 is connected to receive the input signal IN.

The connecting portion on the other side of the transistor MP5 is respectively connected with the gates of the transistors MN7, MN8, MN10 and the connecting portion on one side of the transistor MN7. The connecting portion on the other side of the transistor MP6 is connected with connecting portions on one side of the transistors MN8, MN9 and the input of the inverter INV1.

Further, the connecting portion on the other side of the transistor MN9 is connected with the connecting portion on one side of the transistor MN10. Connecting portions on the other sides of the transistors MN7, MN8, MN10 are respectively connected with the reference potential VSS.

Also, by this constitution, similar to FIG. 8, the Low level input voltage ViL, the High level input voltage ViH and the hysteresis are made to depend only on the reference voltage VREF, and fluctuations in the characteristics can considerably be reduced.

The input circuit of the invention is suitable for restraining fluctuation in the characteristics according to the threshold voltage, temperature and power source voltage of an input circuit in a bus interface.

1. A semiconductor integrated circuit device comprising:
a differential input circuit for comparing an input signal and a reference voltage when the input signal shifts from a Hi level to a Lo level and outputting an inverse signal when the input signal voltage reduces to substantially the same as the voltage level of the reference voltage; and
an input circuit having a hysteresis generating portion for generating a desired hysteresis.

2. The semiconductor integrated circuit device according to claim 1, wherein the differential input circuit comprises a current mirror circuit, and a first and a second transistor coupled with the current mirror circuit for comparing the voltage level of the reference voltage and the voltage level of the input signal.

3. A semiconductor integrated circuit device comprising an input circuit comprising:
a hysteresis generating portion for generating a desired hysteresis; and
a differential input circuit for comparing an input signal and a reference voltage when the input signal shifts from a Hi level to a Lo level and outputting an inverse signal when the voltage of the input signal lowers to substantially the same as the reference voltage, and when the input signal shifts from the Lo level to the Hi level, outputting the inverse signal when the voltage level of the input signal increase to a level higher than the reference voltage, by providing the hysteresis generating portion.

4. The semiconductor integrated circuit device according to claim 3, wherein the differential input circuit comprises:
a current mirror circuit;
a first and a second transistor coupled with the current mirror circuit for comparing the voltage level of the reference voltage and the voltage level of the input signal ; and
wherein the hysteresis generating portion comprises a third transistor coupled with the current mirror circuit and a current substantially proportional to the current flowing in the current mirror circuit is made to flow in the third transistor.

5. The semiconductor integrated circuit device according to any of claim 1, wherein the differential input portion comprises:
a current source transistor constituting a constant current source of the differential input circuit.

6. The semiconductor integrated circuit device according to any of claim 1, wherein the voltage level of the input signal inputted to the differential input circuit is a voltage ranging from a reference potential to a power source voltage.

7. The semiconductor integrated circuit device according to any of claim 1, further comprising:
an I²C bus interface which is an interface in an I²C bus;
wherein the input circuits are respectively provided at a serial data input portion and a serial clock input portion in the I²C bus interface.

8. The semiconductor integrated circuit device according to any of claim 1, further comprising:
a processor for controlling a camera module;
wherein the I²C bus interface is connected to the camera module via the I²C bus, and the processor controls the camera module via the I²C bus.
